(19) United States
(12) Patent Application Publication
(10) Pub. No.: US 2025/0023503 A1
(43) Pub. Date: Jan. 16, 2025

(54) System Comprising Photovoltaic Modules with Multiple Vanes and Corresponding Arranging Method

(71) Applicants: IMEC VZW, Leuven (BE); Katholieke Universiteit Leuven, Leuven (BE); Kuwait University, Safat (KW)

(72) Inventors: Raed I H M Bourisli, Rawda (KW); Bader S H M Aldalali, Safat (KW); Arttu Tuomiranta, Hasselt (BE); Mohammed Gofran Chowdhury, Mechelen (BE); Jef Poortmans, Kessel-Lo (BE)

(21) Appl. No.: 18/713,484

(22) PCT Filed: Nov. 10, 2022
(86) PCT No.: PCT/EP2022/081386

§ 371 Date: May 24, 2024

(30) Foreign Application Priority Data
Dec. 15, 2021 (EP) 21214596.5

(51) Int. Cl. H02S 20/00; H02S 40/42

(52) U.S. Cl. CPC H02S 20/00; H02S 40/425

(57) ABSTRACT

A system comprises at least two photovoltaic modules each comprising a respective module area being substantially perpendicular to the thickness of the corresponding photovoltaic module. Each of the at least two module areas comprises at least one of two first sides being substantially perpendicular to the thickness of the corresponding photovoltaic module and/or two second sides being substantially perpendicular to the thickness of the corresponding photovoltaic module. In this context, the at least two module areas are arranged in a substantially parallel manner with respect to each other and are shifted with respect to each other in an extension direction of the system. In addition to this, the at least two module areas are arranged in a staggering or alternating or ascending or descending manner with respect to an extension plane in the extension direction of the system.

### CROSS-REFERENCE TO RELATED APPLICATIONS

The present application is a non-provisional patent application claiming priority to international application No. PCT/EP2022/081386, filed Dec. 15, 2021, the contents of which are hereby incorporated by reference.

### FIELD OF THE DISCLOSURE

The present disclosure relates to a system comprising at least two photovoltaic modules, wherein the system and/or at least one of the at least two photovoltaic modules comprises multiple vanes, especially for trapping and/or guiding wind to the corresponding photovoltaic module or the system, respectively, and a corresponding method for arranging said at least two photovoltaic modules.

### BACKGROUND

Generally, in times of an increasing importance of renewable energy generation, especially photovoltaic power plants, there is a growing need of reducing the temperature of respective photovoltaic modules because high photovoltaic module temperatures reduce their efficiency. One reason for the high module temperature is the actual geometry of the module which makes releasing energy to its surroundings rather difficult. Heat typically builds up on the frontside and/or the backside of the photovoltaic module, i.e., the wake region, where low wind velocities are normally experienced and where heat is usually trapped.

JP 2013-093377 A relates to a photovoltaic power generation panel comprising a panel body in the shape of a plurality of louvers arranged vertically while spaced apart vertically by a passage; a straightening plate provided on the upper side of the panel body located at the uppermost part; and an outlet provided in the straightening plate and discharging air from the rear of the panel so as to be distributed along the panel surface of the panel body located at the uppermost part. The panel passage between the panel bodies. Disadvantageously, due to the configuration of said photovoltaic power generation panel, air or wind, respectively, is inefficiently distributed, which only leads to a limited cooling effect of the panel surface, the cooling effect furthermore being limited to a narrow range of wind directions, and thus only leading to a limited improvement of the efficiency of the panel.

### SUMMARY

The present disclosure provides a system comprising at least two photovoltaic modules, wherein the system and/or at least one of the at least two photovoltaic modules includes multiple vanes for trapping and guiding wind to the corresponding photovoltaic module.

The present disclosure further includes a method for arranging said at least two photovoltaic modules such that multiple vanes are arranged to trap and guide wind to the least two photovoltaic modules.

In one example embodiment, a system is provided that includes at least two photovoltaic modules, each comprising a respective module area being substantially perpendicular to the thickness of the corresponding photovoltaic module, each of the at least two module areas comprising at least one of two first sides being substantially perpendicular to the thickness of the corresponding photovoltaic module and/or two second sides being substantially perpendicular to the thickness of the corresponding photovoltaic module. In this context, the at least two module areas are arranged in a substantially parallel manner with respect to each other and are shifted with respect to each other in an extension direction of the system. In addition to this, the at least two module areas are arranged in a staggering or alternating or ascending or descending manner with respect to an extension plane in the extension direction of the system. Further additionally, the system and/or at least one of the at least two photovoltaic modules comprises multiple vanes being arranged in a region of at least one of the two first sides and/or the two second sides of the respective module area of the corresponding photovoltaic module.

In some examples, wind can be directed in a highly efficient manner to the photovoltaic modules, thereby especially reducing temperature, and thus increasing efficiency, of the latter. In this context, an easy installation and low costs can be ensured. Further in some examples, no changes in respective production lines of photovoltaic modules and no maintenance are necessary.

With respect to the above-mentioned staggering manner, it is noted that in accordance with said staggering manner, a first module area, especially module areas with an odd number in the extension direction, may be arranged in such a manner that said first module area faces a first surface of the extension plane, whereas a second module area, especially module areas with an even number in the extension direction, may be arranged in such a manner that said second module area faces a second surface of the extension plane. In other words, a first module area of a first photovoltaic module, especially module areas of photovoltaic modules with an odd sequence number in the extension direction, may be located at a first face of the extension plane, whereas a module area of a second photovoltaic module, especially module areas of photovoltaic modules with an even sequence number in the extension direction, may be located at a second, opposite, face of the extension plane. In this context, the distance of each of the module areas from the extension plane has not necessarily to be constant.

With respect to the above-mentioned ascending manner, it is noted that in accordance with said ascending manner, the module areas of the at least two photovoltaic modules may be arranged in such a manner that all said module areas face a same surface of the extension plane. In other words, located at a same face of the extension plane. In this context, the distance of each of the module areas from the extension plane is typically increasing in the extension direction.

With respect to the above-mentioned descending manner, it is noted that in accordance with said ascending manner, the module areas of the at least two photovoltaic modules may be arranged in such a manner that all said module areas face a same surface of the extension plane. In other words, the module area of each of the photovoltaic modules may be located at a same face of the extension plane. In this context, the distance of each of the module areas from the extension plane is typically decreasing in the extension direction.

Moreover, in some examples, a structure for attaching the multiple vanes to the system and/or at least one of the at least two photovoltaic modules may be configured in a manner that wind can pass between the respective vanes and a surface, especially a front surface and/or a back surface, of the corresponding photovoltaic module.

With respect to the above-mentioned structure for attaching the multiple vanes, it is noted that said structure may especially comprise at least one, at least two, crosspiece and/or at least one, at least two, bridge or bridge element, respectively.

It is further noted that the two first sides of the respective module area of the corresponding photovoltaic module may be substantially parallel with respect to each other. In addition to this or as an alternative, the two second sides of the respective module area of the corresponding photovoltaic module may be substantially parallel with respect to each other. Further additionally or further alternatively, at least one of the two first sides of the respective module area of the corresponding photovoltaic module may be substantially perpendicular to at module.

According the present disclosure, at least one, each, of the multiple vanes is configured to trap wind and/or to guide wind to a front surface being substantially parallel to the respective module area and/or a back surface being opposite to the front surface of the corresponding photovoltaic module and/or to the system. In some examples, for instance, both sides of the corresponding photovoltaic module can be cooled, which leads to an increased efficiency of the corresponding photovoltaic module.

With respect to the front surface or the back surface, respectively, it is noted that the front surface of a photovoltaic cell or of a photovoltaic module especially refers to the surface adapted for being oriented towards a light source and thus for receiving illumination. However, in case of bifacial photovoltaic cells or modules, both surfaces are adapted to receive impinging light. In such case, the front surface is the surface adapted for receiving the largest fraction of the light or illumination. The back surface or rear surface of a photovoltaic cell or a photovoltaic module is the surface opposite to the front surface.

It is further noted that the front surface or the back surface of the corresponding photovoltaic module may comprise the respective module area. Alternatively, the respective module area may be located between, especially in the middle between, the front surface and the back surface of the corresponding photovoltaic module.

According to the present disclosure, the respective distance of at least one, especially each, of the at least two module areas from the extension plane is a multiple, such as a triple, a double, and in some instances between 0.9- and 1.1-times, of the thickness of the corresponding photovoltaic module. In this manner, wind guiding can further be improved, which, for instance, leads to an increased air velocity, thereby ensuring a better cooling of the modules, and thus increasing their efficiency.

According to the present disclosure, each or at least one of the at least two module areas is arranged at a tilt angle with respect to the extension plane and/or a horizontal plane. For example, by taking the geographical location of the system and the dominant wind direction into account, efficiency of the photovoltaic modules can further be increased in a highly efficient manner through a tilt angle being adapted accordingly.

According to the present disclosure, the tilt angle is between 5 and 40 degrees, such as between 10 and 35 degrees. In this manner, wind guiding can further be improved, thereby enhancing efficiency of the photovoltaic modules through better cooling.

According to the present disclosure, a gap between each pair of the at least two module areas in the extension direction is between 0.045- and 0.055-times, such as 0.05-times, of a dimension of one of the two first sides or the two second sides of one of the module areas of the respective pair. In some examples, such a gap does not only allow for further improving wind guiding but also for preventing shading of the photovoltaic modules, which, especially in synergistic combination, increases output power of the photovoltaic modules.

According to the present disclosure, at least one, each, of the multiple vanes is configured in a curved manner and comprises a vane radius of curvature. In some examples, the multiple vanes can be manufactured in an easy, and thus cost-efficient, manner.

According to the present disclosure, the vane radius of curvature is between 4 and 6 centimeters, such as between 4.5 and 5.5 centimeters, between 4.8 and 5.2 centimeters, and in some instances at 5 centimeters, for the case that the respective ones of the multiple vanes are located within a bottom volume comprising a back surface being opposite to a front surface of the corresponding photovoltaic module but not the front surface of the corresponding photovoltaic module.

In addition to this or as an alternative, the vane radius of curvature is between 16 and 22 centimeters, such as between 18 and 20 centimeters, for the case that the respective ones of the multiple vanes are located within a top volume comprising a front surface of the corresponding photovoltaic module but not a back surface being opposite to the front surface of the corresponding photovoltaic module.

In some examples, for instance, such radii allow for an optimum wind guiding, which leads to a particularly high efficiency of the photovoltaic modules.

Further in some examples, such a larger vane radius of curvature for the top vanes exemplarily leads to a better cooling effect especially for 135 and 180 degree wind directions.

According to the present disclosure, at least one, each, of the multiple vanes is configured in a curved manner and comprises a vane arc length. For example, complexity of manufacturing such vanes can further be reduced, thereby allowing for an increased cost-efficiency.

According to the present disclosure, the vane arc length, as mentioned above, depends on the tilt angle, as mentioned above, and/or the vane radius of curvature, as mentioned above. For instance, such a dependency allows for further improving wind guiding, which leads to a better cooling, thereby increasing efficiency of the photovoltaic modules.

According to the present disclosure, the vane arc length, as mentioned above, is determined according to the following formula:

$$\\ \frac{2 π ( θ + 10 )}{360} \times ROC .$$

In this context, θ denotes the tilt angle, especially as mentioned above, and ROC denotes the vane radius of curvature, as mentioned above. For example, the complexity of the above-mentioned dependency can be reduced to a minimum, thereby ensuring manufacturing the vanes in a highly cost-efficient manner.

Further, this also allows for further improving wind guiding towards the photovoltaic modules.

According to the present disclosure in an example configuration between 30 and 70 percent, such as between 33 and 67 percent, and between 40 and 60 percent, and in some instance 50 percent (half), of the multiple vanes may be located within a top volume comprising a front surface of the corresponding photovoltaic module but not a back surface being opposite to the front surface of the corresponding photovoltaic module. For instance, wind guiding can be improved with special respect to the front surface of the corresponding photovoltaic module, which enhances cooling of the front surface in a highly efficient manner.

According to the present disclosure in an example configuration, between 30 and 70 percent, such as between 33 and 67 percent, and between 40 and 60 percent, and in some instance s 50 percent (half), of the multiple vanes is located within a bottom volume comprising a back surface being opposite to a front surface of the corresponding photovoltaic module but not the front surface of the corresponding photovoltaic module. For example, wind guiding can be improved with special respect to the back surface of the corresponding photovoltaic module, which enhances cooling of the back surface in a particularly efficient manner.

According to the present disclosure, a method for arranging at least two photovoltaic modules, each comprising a respective module area being substantially perpendicular to the thickness of the corresponding photovoltaic module, each of the at least two module areas comprising at least one of two first sides being substantially perpendicular to the thickness of the corresponding photovoltaic module and/or two second sides being substantially perpendicular to the thickness of the corresponding photovoltaic module, is provided. Said method comprises the steps of arranging the at least two module areas in a substantially parallel manner with respect to each other, shifting the at least two module areas with respect to each other in an extension direction of the at least two photovoltaic modules, and arranging the at least two module areas in a staggering or alternating or ascending or descending manner with respect to an extension plane in the extension direction of the at least two photovoltaic modules. In this context, said method further comprises arranging multiple vanes in a region of at least one of the two first sides and/or the two second sides of the respective module area of the corresponding photovoltaic module.

In some examples, wind can be directed in a highly efficient manner to the photovoltaic modules, thereby reducing temperature, and thus increasing efficiency, of the latter. In this context, an easy installation at low costs can be ensured. Further, no changes in respective production lines of photovoltaic modules and no additional maintenance are necessary.

With respect to the above-mentioned staggering manner, it is noted that in accordance with said staggering manner, a first module area, especially module areas with an odd number in the extension direction, may be arranged in such a manner that said first module area faces a first surface of the extension plane, whereas a second module area, especially module areas with an even number in the extension direction, may be arranged in such a manner that said second module area faces a second surface of the extension plane. In other words, a first module area of a first photovoltaic module, especially module areas of photovoltaic modules with an odd sequence number in the extension direction, may be located at a first face of the extension plane, whereas a second module area of a second photovoltaic module, module areas of photovoltaic modules with an even sequence number in the extension direction, may be located at a second, opposite, face of the extension plane. In this context, the distance of each of the module areas from the extension plane has not necessarily to be constant.

With respect to the above-mentioned alternating manner, it is noted that in accordance with said alternating manner, a first module area, especially module areas with an odd number in the extension direction, may be arranged in such a manner that said first module area faces a first surface of the extension plane, whereas a second in the extension direction, may be arranged in such a manner that said second module area faces a second surface of the extension plane. In other words, a first module area of a first photovoltaic module, such as module areas of photovoltaic modules with an odd sequence number in the extension direction, may be located at a first face of the extension plane, whereas a second module area of a second photovoltaic module, such as module areas of photovoltaic modules with an even sequence number in the extension direction, may be located at a second, opposite, face of the extension plane. In this context, the distance of each of the module areas from the extension plane is typically constant.

With respect to the above-mentioned ascending manner, it is noted that in accordance with said ascending manner, the module areas of the at least two photovoltaic modules may be arranged in such a manner that all said module areas face a same surface of the extension plane. In other words, the module area of each of the photovoltaic modules may be located at a same face of the extension plane. In this context, the distance of each of the module areas from the extension plane is typically increasing in the extension direction.

With respect to the above-mentioned descending manner, it is noted that in accordance with said ascending manner, the module areas of the at least two photovoltaic modules may be arranged in such a manner that all said module areas face a same surface of the extension plane. In other words, the module area of each of the photovoltaic modules may be located at a same face of the extension plane. In this context, the distance of each of the module areas from the extension plane is typically decreasing in the extension direction.

Moreover, In some examples a structure for attaching the multiple vanes to the at least two photovoltaic modules and/or at least one of the at least two photovoltaic modules may be configured in a manner that wind can pass between the respective vanes and a surface, especially a front surface and/or a back surface, of the corresponding photovoltaic module.

In other words, in some examples the method comprises the step of configuring a structure for attaching the multiple vanes to the at least two photovoltaic modules and/or at least one of the at least two photovoltaic modules in a manner that wind can pass between the respective vanes and a surface, especially a front surface and/or a back surface, of the corresponding photovoltaic module.

With respect to the above-mentioned structure for attaching the multiple vanes, it is noted that said structure may especially comprise at least one, at least two, crosspiece and/or at least one, at least two, bridge or bridge element, respectively.

It is further noted that the two first sides of the respective module area of the corresponding photovoltaic module may be substantially parallel with respect to each other. In addition to this or as an alternative, the two second sides of the respective module area of the corresponding photovoltaic module may be substantially parallel with respect to each other. Further additionally or further alternatively, at least one of the two first sides of the respective module area of the corresponding photovoltaic module may be substantially perpendicular to at module.

According to the present disclosure, the method further comprises the step of configuring at least one, each, of the multiple vanes to trap wind and/or to guide wind to a front surface being substantially parallel to the respective module area and/or a back surface being opposite to the front surface of the corresponding photovoltaic module and/or to the at least two photovoltaic modules.

In some examples, for instance, both sides of the corresponding photovoltaic module can be cooled, which leads to an increased efficiency of the corresponding photovoltaic module.

With respect to the front surface or the back surface, respectively, it is noted that the front surface of a photovoltaic cell or of a photovoltaic module especially refers to the surface adapted for being oriented towards a light source and thus for receiving illumination. However, in case of bifacial photovoltaic cells or modules, both surfaces are adapted to receive impinging light. In such case, the front surface is the surface or side adapted for receiving the largest fraction of the light or illumination. The back surface or rear surface, of a photovoltaic cell or a photovoltaic module is the surface opposite to the front surface.

It is further noted that the front surface or the back surface of the corresponding photovoltaic module may comprise the respective module area. Alternatively, the respective module area may be located between, especially in the middle between, the front surface and the back surface of the corresponding photovoltaic module.

### BRIEF DESCRIPTION OF THE DRAWINGS

Exemplary embodiments of the present disclosure are now further explained with respect to the drawings by way of example only, and not for limitation. In the drawings:

FIG. 1A shows an exemplary embodiment of a system comprising four photovoltaic modules;

FIG. 1B shows a further exemplary embodiment of a system comprising four photovoltaic modules;

FIG. 2 shows a further exemplary embodiment of a system comprising two photovoltaic modules;

FIG. 3 shows an exemplary finite element method model in the context of an exemplary system;

FIG. 4A shows exemplary contours of velocity magnitude around an exemplary conventional photovoltaic array;

FIG. 4B shows exemplary contours of velocity magnitude around an exemplary photovoltaic array in the sense of the present disclosure;

FIG. 5A shows exemplary contours of temperature around an exemplary conventional photovoltaic array;

FIG. 5B shows exemplary contours of temperature around an exemplary photovoltaic array in the sense of the present disclosure;

FIG. 6A shows exemplary contours of temperature around the fourth and final module in an exemplary conventional photovoltaic array;

FIG. 6B shows exemplary contours of temperature around the fourth and final module in an exemplary photovoltaic array in the sense of the present disclosure;

FIG. 7A shows exemplary three-dimensional contours of temperature for the modules of an exemplary conventional photovoltaic array;

FIG. 7B shows exemplary three-dimensional contours of temperature for the modules of an exemplary photovoltaic array in the sense of the present disclosure;

FIG. 8 illustrates individual maximum temperatures in each of the modules for an exemplary conventional photovoltaic array and an exemplary photovoltaic array in the sense of the present disclosure; and

FIG. 9 shows a flow chart of an embodiment of the second aspect of the present disclosure.

### DETAILED DESCRIPTION

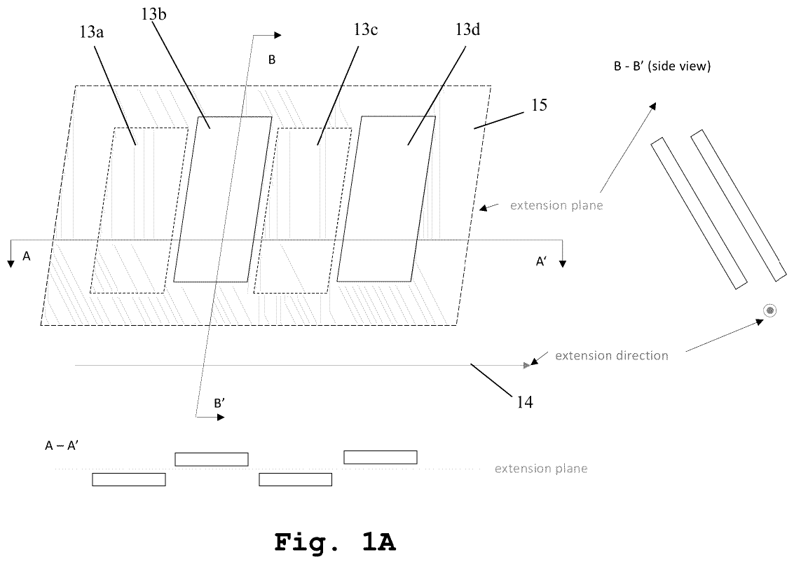

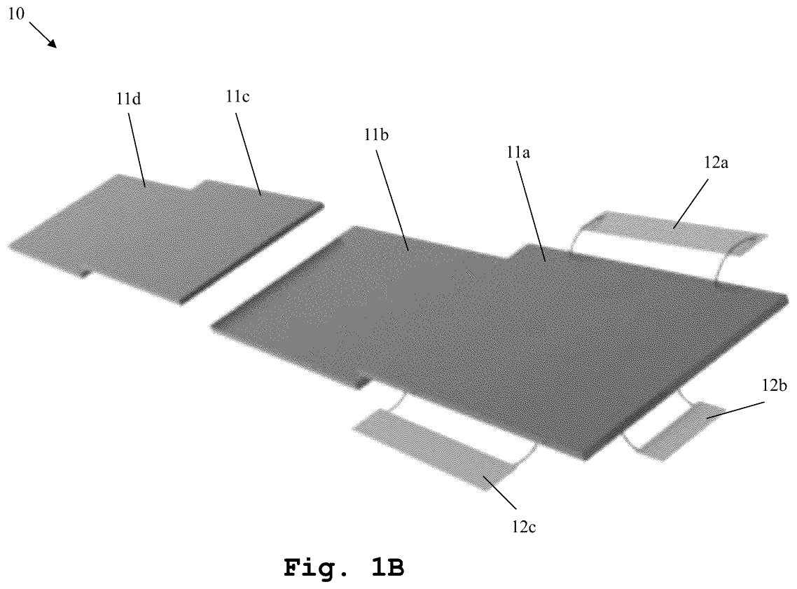

FIG. 1A depicts an exemplary embodiment of an inventive system exemplarily comprising four photovoltaic modules 13a, 13b, 13c, 13d.

As it can be seen from FIG. 1A, each of said four photovoltaic modules 13a, 13b, 13c, 13d comprises a respective module area being substantially perpendicular, exemplarily perpendicular, to the thickness of the corresponding photovoltaic module 13a, 13b, 13c, 13d.

Furthermore, each of the four module areas comprises at least one of two first sides being substantially perpendicular, exemplarily perpendicular, to the thickness of the corresponding photovoltaic module 13a, 13b, 13c, 13d and two second sides being substantially perpendicular, exemplarily perpendicular, to the thickness of the corresponding photovoltaic module 13a, 13b, 13c, 13d.

In this context, the four module areas are arranged in a substantially parallel, exemplarily parallel, manner with respect to each other and are shifted with respect to each other in an extension direction 14 of the system according to FIG. 1A.

In addition to this, the four module areas are exemplarily arranged in an alternating manner with respect to an extension plane 15 in the extension direction 14 of the system illustrated by FIG. 1A.

With respect to FIG. 1B, an exemplary embodiment 10 of an example system comprising at least two photovoltaic modules is shown. In this exemplary case, as it can be seen, the system comprises four photovoltaic modules 11a, 11b, 11c, 11d. In this context, multiple vanes 12a, 12b, 12c, such as guiding vanes, and in particular wind guiding vanes, are attached to the first module 11a of said photovoltaic modules 11a, 11b, 11c, 11d.

In addition to this, the remaining photovoltaic modules 11b, 11c, 11d or panels, respectively, of the system or the photovoltaic array, respectively, are periodically staggered to simulate the effect of the above-mentioned vane 12b for the respective other modules.

In some examples, it is noted that the combination of staggering of the modules with vanes 12a and 12c enables capturing wind from many different wind directions.

Generally, such a configuration as illustrated by FIG. 1B increases the air velocity at the front surface and/or the back surface of the respective panels especially to enhance heat transfer by convection and lower the module temperature. This is exemplarily done by affixing especially-designed guiding-vane(s) in critical areas on the peripheries of the corresponding module to aid in the channeling of wind to the frontside and/or the backside of the corresponding module.

Furthermore, it is also generally noted that vanes, guiding vanes, can be placed on one or more sides of the corresponding module, to capture wind from multiple directions. The dimensions and locations of the vanes can be optimized based on the geographical location and/or the dominant wind direction.

Additionally or alternatively, the vanes, especially guiding vanes, on the top and bottom can cover single modules or be extended to cover multiple ones. Moreover, especially in the case of photovoltaic arrays, and to complement the effect of these vanes, the modules themselves may be staggered in and out of plane especially to simulate the effect of multiple vanes.

For the sake of completeness, it is to be pointed out that present disclosure typically leads to the following results:

With respect to production lines of photovoltaic modules, no changes have to be made.

An easy installation of the photovoltaic modules and of the vanes can be ensured.

Low costs can be guaranteed: an efficient cooling of the photovoltaic modules is realized in a passive way, not consuming power.

Additional maintenance is not required, as the vanes do not require any maintenance.

The present disclosure is immediately deployable in current photovoltaic power plants.

The present disclosure is effective for a broad range of wind directions.

The present disclosure is effective for enhanced heat transfer both at the front and back surface of the photovoltaic modules. The present disclosure is suitable for systems comprising bifacial photovoltaic modules.

In addition to this, it can especially be summarized that the present disclosure revolves around the addition of especially-designed guiding vanes in specific areas along the perimeter of the corresponding photovoltaic module. These vanes typically guide the surrounding wind toward dead zones around the corresponding module where heat could be trapped.

This especially increases the air velocity at both front and back surfaces of the corresponding module which reduces the operating temperature of the module, and this increases its efficiency. Moreover, especially for the case of an array of photovoltaic modules, the guiding vanes can be installed individually, or, for ease of manufacturing and installation, be extended through the width of the array.

Further, the modules can also be installed in a staggered configuration, in- and out-of-plane, especially to simulate the effect of the guiding vanes longitudinally.

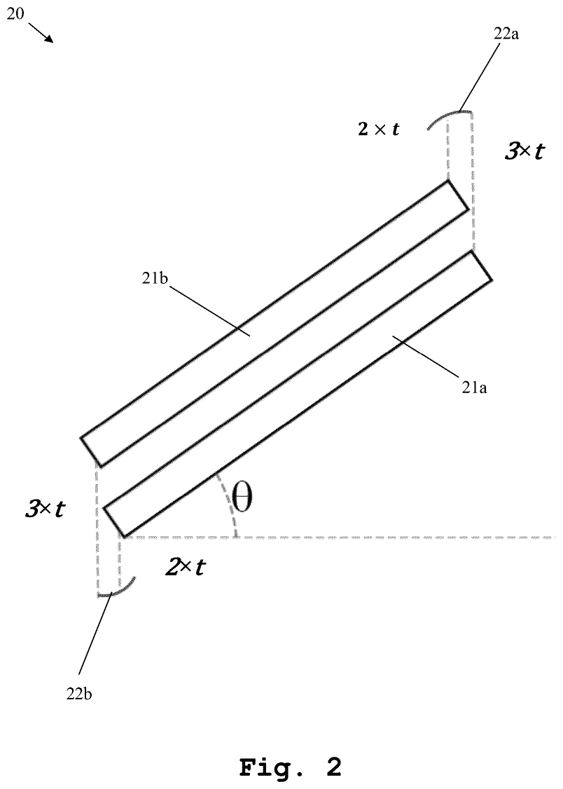

Now, with respect to FIG. 2, an exemplary embodiment 20 of an inventive system is shown. In this exemplary case, as it can be seen, the system comprises two photovoltaic modules 21a, 21b. Specifically, FIG. 2 is a side view showing two staggered modules 21a, 21b with top and bottom vanes 22a, 22b.

In some examples, all required specifications may be in terms of either module thickness (t) or module length (1) or module tilt angle (0). Further, in terms of module dimensions, the vanes 22a, 22b and staggering can be applied to any commercially available module.

In this context, for the module tilt angle θ, the following range may be used: 10°-35°. Furthermore, for staggering, especially in- and out-of-plane arrangement of modules, the following may apply: 1*t±10%. Additionally or alternatively, for at least one, especially each, gap in extension direction between modules, the following may apply: 0.05*1±10%.

Moreover, for a vane radius of curvature (ROC), 5 cm±10% may apply, whereas for a vane arc length, the following may apply:

$$\\ \frac{2 π ( θ + 10 )}{360} \times ROC .$$

Although the present disclosure is illustrated and described above in particular for exemplary embodiments of a system wherein the at least two photovoltaic modules are arranged in a 1D array (i.e. in a row), it is not limited thereto. In embodiments of a system according to the present disclosure, the photovoltaic modules may be arranged in a 2D array, i.e. the photovoltaic modules may be arranged in a matrix configuration comprising multiple rows, e.g. multiple parallel rows of photovoltaic modules.

In embodiments wherein the photovoltaic modules are arranged in a 2D array, arranging the module areas in a staggering manner may comprise arranging the module areas such that neighboring modules are arranged in a staggering manner in both main directions of the 2D array, e.g. in two substantially orthogonal directions of the 2D array, e.g. in a first direction corresponding to a direction of a row of photovoltaic modules and in a second direction corresponding to a direction substantially orthogonal to a row of photovoltaic modules. In other words, the photovoltaic modules may be staggered according to a checkerboard pattern.

In embodiments wherein the photovoltaic modules are arranged in a 2D array, arranging the module areas in an alternating manner may comprise arranging the module areas such that neighboring modules are arranged in an alternating manner in both main directions of the 2D array, e.g. in two substantially orthogonal directions of the 2D in a first direction corresponding to a direction of a row of photovoltaic modules and in a second direction corresponding to a direction substantially orthogonal to a row of photovoltaic modules. In other words, the photovoltaic modules may be alternated according to a checkerboard pattern.

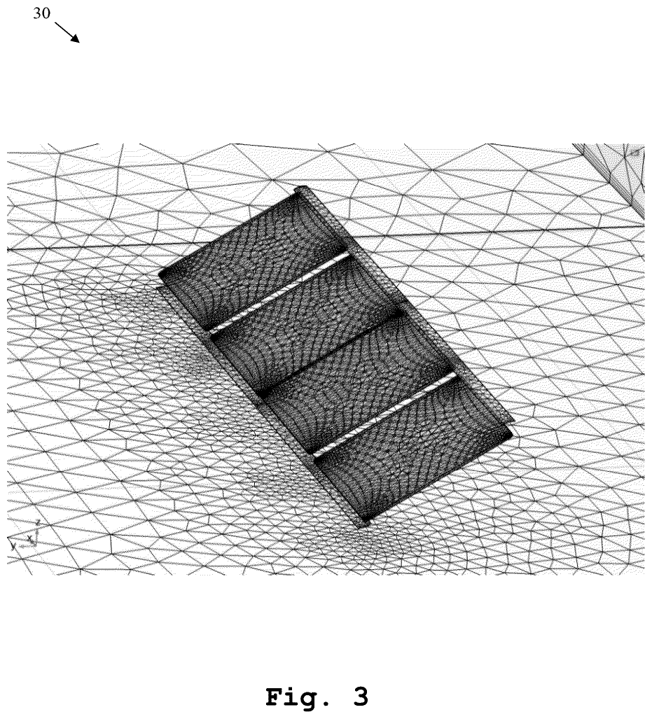

FIG. 3 illustrates an exemplary finite element method (FEM) model, especially a three-dimensional FEM model 30, in the context of an exemplary inventive system such as the above-mentioned system 10 according to FIG. 1B with four photovoltaic modules.

Said three-dimensional FEM model has been tested under the following assumptions:
Inclination angle of the photovoltaic modules is 30° from the horizontal plane and facing south.
Irradiance is 1000 W/m².
Module efficiency of 20%.
Wind direction 50th-percentile of annual measurements in Kuwait (1-hour resolution).
Ambient temperature is 50th-percentile of annual measurements in Kuwait (1-hour resolution).
Top and bottom vanes, such as vanes 12a and 12c of FIG. 1B, have been extended for the entire width of the array.
No side vanes, such as vane 12b of FIG. 1B, were used for the simulation.

It is further noted that the FEM model has been run for five different incoming wind directions, from 0 to 180° (with 45°-increments), 0 being due south, with and without the vanes, such as guiding vanes.

The model has been limited to the module only, i.e., without inverters, cabling, junction boxes, etc. The module especially is a glass-glass module. The silicon and encapsulant layers were thermally lumped with the glass layer. This simplifies the FEM model by avoiding the modeling of the widely differing scales. This is justified by the fact that these layers account for negligible fractions of the energy conducted, due to their very small thickness. In this context. FIG. 3 shows a partial view of the meshed domain.

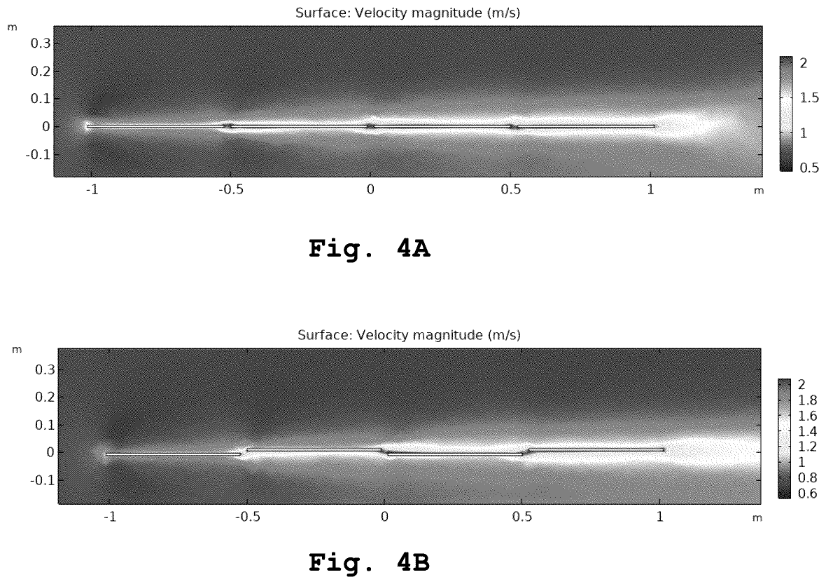

Now, with respect to FIG. 4A, contours of velocity magnitude around an exemplary conventional photovoltaic array are shown, whereas FIG. 4B illustrates contours of velocity magnitude around an exemplary staggered array in the sense of the present disclosure for the case of 90 degrees incoming wind direction.

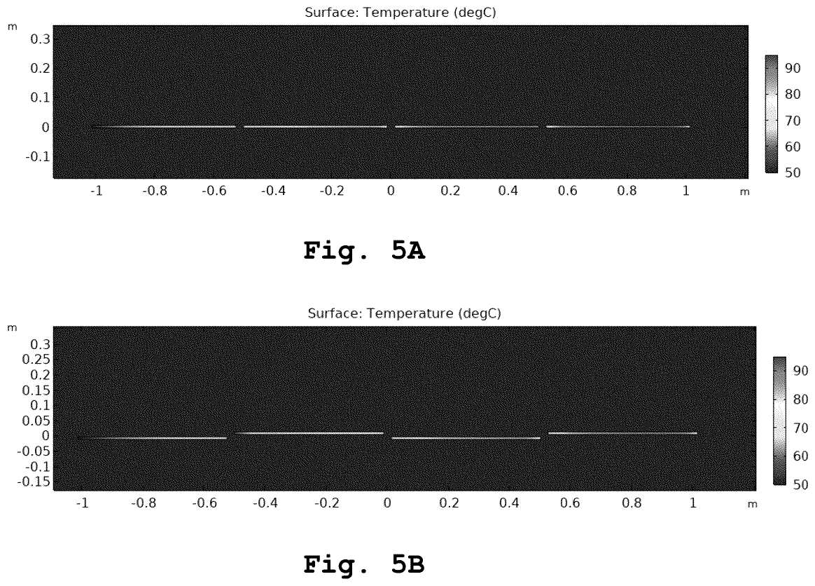

By analogy with FIG. 4A and FIG. 4B, FIG. 5A depicts contours of temperature around an exemplary conventional photovoltaic array, whereas FIG. 5B shows contours of temperature around an exemplary staggered array in the sense of the present disclosure.

In some examples, it can be seen from FIG. 4A or FIG. 4B, respectively, that staggering especially allows cool air from the surroundings to pass through in-between the modules, lowering the temperature as it can be seen in FIG. 5A or FIG. 5B, respectively. Exemplarily, the maximum temperature in the array may be reduced by more than 5.6 degrees Celsius for the case of the 90° incoming wind direction.

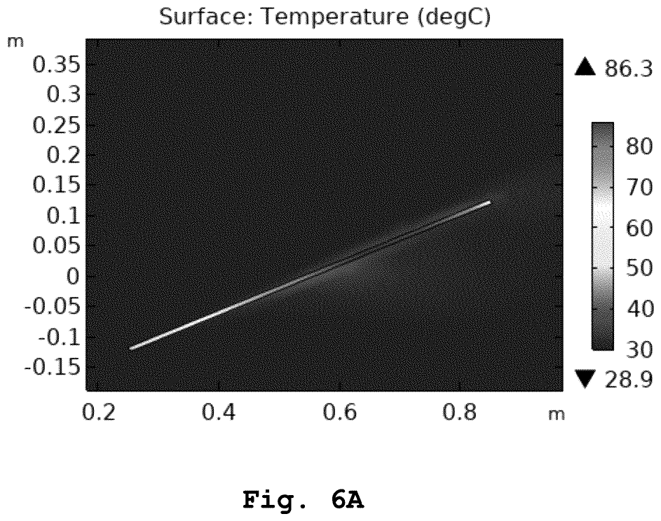

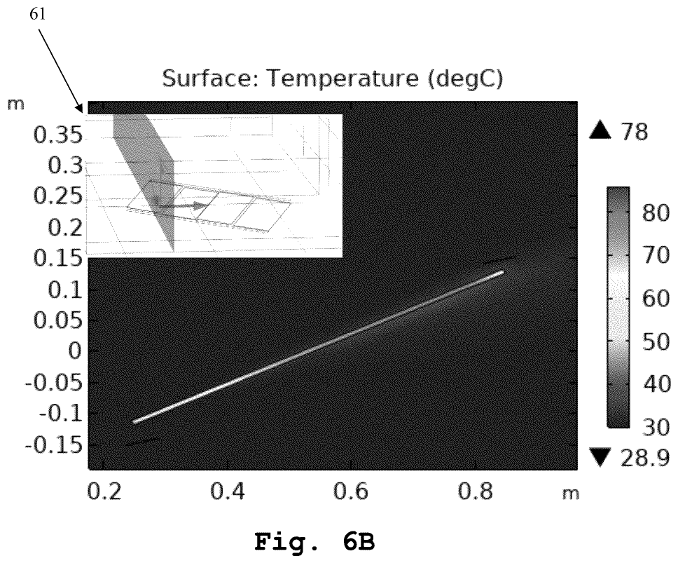

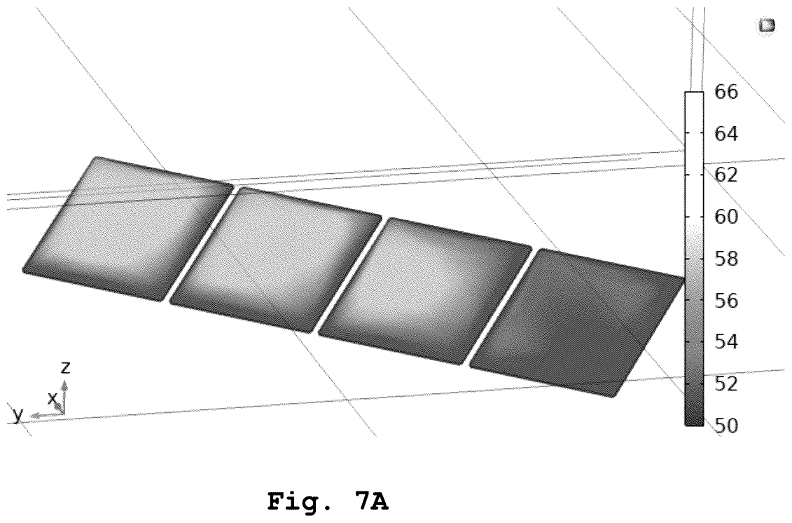

Further exemplarily, the corresponding 45 degrees incoming wind case elucidates the efficacy of the guiding vanes. FIG. 6A or FIG. 6B, respectively, show the temperature contours around the fourth module for the cases without (FIG. 6A) and with the inventive guiding vanes and staggering (FIG. 6B). In this context, the insert 61 in FIG. 6B shows the location of the respective two-dimensional cut in the domain.

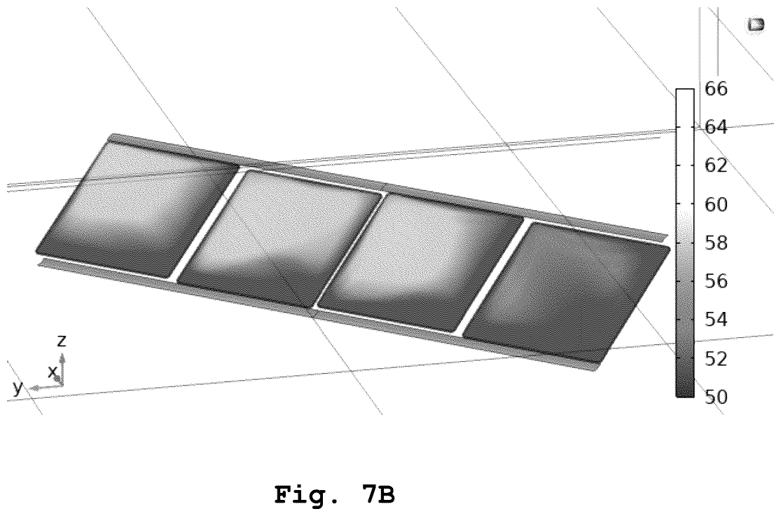

In addition to this, for this exemplary case. FIG. 7A or FIG. 7B, respectively, also show the corresponding three-dimensional temperature contours in the modules. Accordingly, said FIG. 7A shows the three-dimensional contours of temperature for the modules of the exemplary conventional photovoltaic array, whereas said FIG. 7B illustrates the three-dimensional contours of temperature for the modules of the exemplary staggered array with guiding vanes in the sense of the present disclosure especially for the case of 45 degrees incoming wind direction.

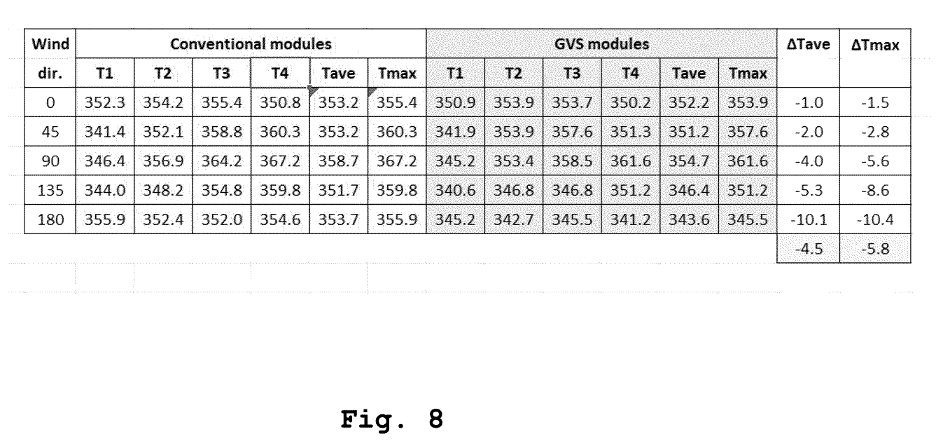

With respect to the above-mentioned conventional and staggered with vanes (GVS) cases, the table according to FIG. 8 especially summarizes the corresponding numerical results. The (reduction) in maximum temperature in each of the four modules for each case is given, as well as the maximum among them and their averages, for each wind direction.

In some examples, as it can be seen from said table of FIG. 8, the use of GVS or the present disclosure, respectively, gives an average reduction of 1.6 degrees Celsius in the maximum module temperature, across all wind directions.

Further, for the sake of completeness, it should be noted that a larger vane radius of curvature for the top vanes exemplarily leads to a better cooling effect especially for the 135 and 180 degree wind directions.

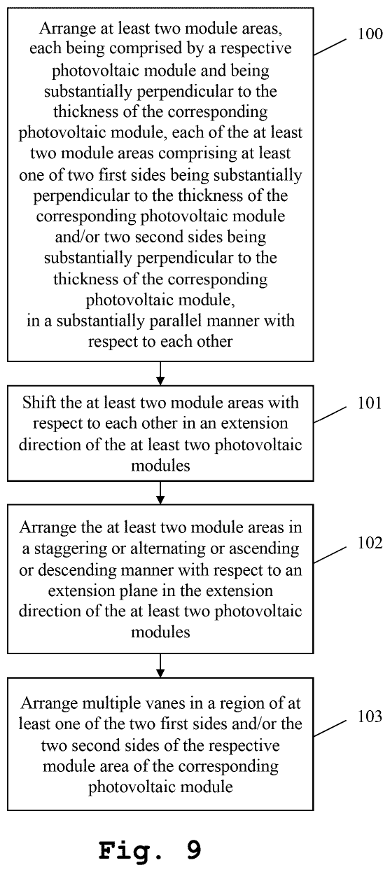

Finally, FIG. 9 shows a flow chart of an embodiment of the inventive method for arranging at least two photovoltaic modules, each comprising a respective module area being substantially perpendicular to the thickness of the corresponding photovoltaic module, each of the at least two module areas comprising at least one of two first sides being substantially perpendicular to the thickness of the corresponding photovoltaic module and/or two second sides being substantially perpendicular to the thickness of the corresponding photovoltaic module. In a first step 100, the at least two module areas are arranged in a substantially parallel manner with respect to each other.

Then, in a second step 101, the at least two module areas are shifted with respect to each other in an extension direction of the at least two photovoltaic modules. Furthermore, in a third step 102, the at least two module areas are arranged in a staggering or alternating or ascending or descending manner with respect to an extension plane in the extension direction of the at least two photovoltaic modules. In a fourth step 103, multiple vanes are arranged in a region of at least one of the two first sides and/or the two second sides of the respective module area of the corresponding photovoltaic module.

It is noted that in some examples the method may further comprises the step of configuring each or at least one, of the multiple vanes to trap wind and/or to guide wind to a front surface being substantially parallel to the respective module area and/or a back surface being opposite to the front surface of the corresponding photovoltaic module and/or to the at least two photovoltaic modules.

It is further noted that the respective distance of at least one, especially each, of the at least two module areas from the extension plane may be a multiple, such as a triple, a double, and in some instances between 0.9- and 1.1-times, of the thickness of the corresponding photovoltaic module.

In other words, the method may additionally or alternatively comprise the step of arranging the at least two photovoltaic modules such that the respective distance of at least one, especially each, of the at least two module areas from the extension plane may be a multiple, such as a triple, a double, and in some instances between 0.9- and 1.1-times, of the thickness of the corresponding photovoltaic module.

Furthermore, each or at least one of the at least two module areas may be arranged at a tilt angle with respect to a horizontal plane. In other words, the method may additionally or alternatively comprise the step of arranging each or at least one of the at least two module areas at a tilt angle with respect to the horizontal plane. In this context, in some examples the tilt angle may be between 5 and 40 degrees, such as between 10 and 35 degrees.

Moreover, it is noted that a gap between each pair of the at least two module areas in the extension direction may be between 0.045- and 0.055-times, such as 0.05-times, of a dimension of one of the two first sides or the two second sides of one of the module areas of the respective pair. In other words, the method may additionally or alternatively comprise the step of arranging the at least two photovoltaic modules such that a gap between each pair of the at least two module areas in the extension direction may be between 0.045- and 0.055-times, such as 0.05-times, of a dimension of one of the two first sides or the two second sides of one of the module areas of the respective pair.

Furthermore, it might be desirable if each or at least one of the multiple vanes is configured in a curved manner and comprises a vane radius of curvature. In other words, the method may additionally or alternatively comprise the step of configuring each or at least one of the multiple vanes in a curved manner, wherein at least one, preferably each, of the multiple vanes comprises a vane radius of curvature. In this context, it might be desirable if the vane radius of curvature is between 4 and 6 centimeters, such as between 4.5 and 5.5 centimeters or between 4.8 and 5.2 centimeters. In some examples, the vane radius of curvature may be 5 centimeters, such as for the case that the respective ones of the multiple vanes are located within a bottom volume comprising a back surface being opposite to a front surface of the corresponding photovoltaic module but not the front surface of the corresponding photovoltaic module.

In addition to this or as an alternative, the vane radius of curvature is between 16 and 22 centimeters, such as between 18 and 20 centimeters for the case that the respective ones of the multiple vanes are located within a top volume comprising a front surface of the corresponding photovoltaic module but not a back surface being opposite to the front surface of the corresponding photovoltaic module.

Moreover, it is noted that each or at least one of the multiple vanes may especially be configured in a curved manner and may comprise a vane arc length. In other words, the method may additionally or alternatively comprise the step of configuring each or at least one of the multiple vanes in a curved manner, wherein each or at least one of the multiple vanes comprises a vane arc length.

It is noted that it might be desirable if the vane arc length, especially as mentioned above, depends on the tilt angle, especially as mentioned above, and/or the vane radius of curvature, as mentioned above.

It is further noted that it might be desirable if the vane arc length, as mentioned above, is determined according to the following formula:

$$\\ \frac{2 π ( θ + 10 )}{360} \times ROC .$$

In this context, θ denotes the tilt angle, as mentioned above, and ROC denotes the vane radius of curvature, as mentioned above.

Furthermore, it might be desirable if between 30 and 70 percent, such as between 33 and 67 percent and between 40 and 60 percent or even 50 percent (half), of the multiple vanes is located within a top volume comprising a front surface of the corresponding photovoltaic module but not a back surface opposite to the front surface of the corresponding photovoltaic module.

In other words, the method may additionally or alternatively comprise the step of locating between 30 and 70 percent, such as between 33 and 67 percent and between 40 and 60 percent, or even 50 percent (half), of the multiple vanes within a top volume comprising a front surface of the corresponding photovoltaic module but not a back surface being opposite to the front surface of the corresponding photovoltaic module.

Moreover, in some example a configuration may include between 30 and 70 percent, such as between 33 and 67 percent and between 40 and 60 percent, or even 50 percent (half), of the multiple vanes is located within a bottom volume comprising a back surface being opposite to a front surface of the corresponding photovoltaic module but not the front surface of the corresponding photovoltaic module.

In other words, the method may additionally or alternatively comprise the step of locating between 30 and 70 percent such as between 33 and 67 percent, and between 40 and 60 percent, or even 50 percent (half), of the multiple vanes within a bottom volume comprising a back surface being opposite to a front surface of the corresponding photovoltaic module but not the front surface of the corresponding photovoltaic module.

While various embodiments of the present disclosure have been described above, it should be understood that they have been presented by way of example only, and not limitation. Numerous changes to the disclosed embodiments can be made in accordance with the disclosure herein without departing from the spirit or scope of the present disclosure. Thus, the breadth and scope of the present disclosure should not be limited by any of the above described embodiments. Rather, the scope of the present disclosure should be defined in accordance with the following claims and their equivalents.

Although the present disclosure has been illustrated and described with respect to one or more implementations, equivalent alterations and modifications will occur to others skilled in the art upon the reading and understanding of this specification and the annexed drawings. In addition, while a particular feature of the present disclosure may have been disclosed with respect to only one of several implementations, such feature may be combined with one or more other features of the other implementations as may be desired and advantageous for any given or particular application.

What is claimed is:

1. A system comprising:
at least two photovoltaic modules, each comprising a respective module area being substantially perpendicular to the thickness of the corresponding photovoltaic module, each of the at least two module areas comprising at least one of two first sides being substantially perpendicular to the thickness of the corresponding photovoltaic module and/or two second sides being substantially perpendicular to the thickness of the corresponding photovoltaic module,
wherein the at least two module areas are arranged in a substantially parallel manner with respect to each other and are shifted with respect to each other in an extension direction of the system,
wherein the at least two module areas are arranged in a staggering or alternating or ascending or descending manner with respect to an extension plane in the extension direction of the system, and
wherein the system and/or at least one of the at least two photovoltaic modules comprises multiple vanes being arranged in a region of at least one of the two first sides and/or the two second sides of the respective module area of the corresponding photovoltaic module.

2. The system according to claim 1, wherein at least one, each, of the multiple vanes is configured to trap wind and/or to guide wind to a front surface being substantially parallel to the respective module area and/or a back surface being opposite to the front surface of the corresponding photovoltaic module and/or to the system.

3. The system according to claim 2, wherein the respective distance of at least one of the at least two module areas from the extension plane is a multiple of the thickness of the corresponding photovoltaic module.

4. The system according to claim 3, wherein at least one, each, of the at least two module areas is arranged at a tilt angle with respect to the extension plane and/or a horizontal plane.

5. The system according to claim 2, wherein at least one, each, of the at least two module areas is arranged at a tilt angle with respect to the extension plane and/or a horizontal plane.

6. The system according to claim 1, wherein at least one, each, of the at least two module areas is arranged at a tilt angle with respect to the extension plane and/or a horizontal plane.

7. The system according to claim 6, wherein the tilt angle is between 5 and 40 degrees, between 10 and 35 degrees.

8. The system according to claim 1, wherein the respective distance of at least one of the at least two module areas from the extension plane is between 0.9- and 1.1-times, of the thickness of the corresponding photovoltaic module.

9. The system according to claim 1, wherein a gap between each pair of the at least two module areas in the extension direction is between 0.045- and 0.055-times, a dimension of one of the two first sides or the two second sides of one of the module areas of the respective pair.

10. The system according to claim 1, wherein at least one, each, of the multiple vanes is configured in a curved manner and comprises a vane radius of curvature.

11. The system according to claim 10, wherein the vane radius of curvature is between 4 and 6 centimeters, for the case that the respective ones of the multiple vanes are located within a bottom volume comprising a back surface being opposite to a front surface of the corresponding photovoltaic module but not the front surface of the corresponding photovoltaic module, and/or wherein the vane radius of curvature is between 16 and 22 centimeters for the case that the respective ones of the multiple vanes are located within a top volume comprising a front surface of the corresponding photovoltaic module but not a back surface being opposite to the front surface of the corresponding photovoltaic module.

12. The system according to claim 11,
wherein at least one, each, of the multiple vanes is configured in a curved manner and comprises a vane arc length.

13. The system according to claim 12, wherein the vane arc length depends on the tilt angle and/or the vane radius of curvature.

14. The system according claim 12, wherein the vane arc length is determined according to the following formula:
$$\\ \frac{2 π ( θ + 10 )}{360} \times ROC ,$$
wherein θ denotes the tilt angle, and
wherein ROC denotes the vane radius of curvature.

15. The system according to claim 1,
wherein at least one, each, of the multiple vanes is configured in a curved manner and comprises a vane arc length.

16. The system according to claim 1, wherein between 30 and 70 percent, of the multiple vanes is located within a top volume comprising a front surface of the corresponding photovoltaic module but not a back surface being opposite to the front surface of the corresponding photovoltaic module.

17. The system according to claim 1, wherein 50 percent (half) of the multiple vanes is located within a bottom volume comprising a back surface being opposite to a front surface of the corresponding photovoltaic module but not the front surface of the corresponding photovoltaic module.

18. A method for arranging at least two photovoltaic modules, each comprising a respective module area being substantially perpendicular to the thickness of the corresponding photovoltaic module, each of the at least two module areas comprising at least one of two first sides being substantially perpendicular to the thickness of the corresponding photovoltaic module, and/or two second sides being substantially perpendicular to the thickness of the corresponding photovoltaic module, the method comprising the steps of:
arranging the at least two module areas in a substantially parallel manner with respect to each other, shifting the at least two module areas with respect to each other in an extension direction of the at least two photovoltaic modules,
arranging the at least two module areas in a staggering or alternating or ascending or descending manner with respect to an extension plane in the extension direction of the at least two photovoltaic modules, and
arranging multiple vanes in a region of at least one of the two first sides and/or the two second sides of the respective module area of the corresponding photovoltaic module.

19. The method according to claim 18,
wherein the method further comprises the step of configuring at least one, each, of the multiple vanes to trap wind and/or to guide wind to a front surface being substantially parallel to the respective module area and/or a back surface being opposite to the front surface of the corresponding photovoltaic module and/or to the at least two photovoltaic modules.
